(19) United States
(12) Patent Application Publication
(10) Pub. No.: US 2003/0082483 A1
(43) Pub. Date: May 1, 2003

(54) Chemically amplified photoresist and process for structuring substrates having resist copolymers with enhanced transparency resulting from fluorinating the photochemically cleavable leaving groups and being applicable to 157 nm photolithography

(76) Inventors: Christoph Hohle, Bubenreuth (DE); Jorg Rottstegge, Erlangen (DE); Christian Eschbaumer, Schwaig (DE); Michael Sebald, Weisendorf (DE)

Correspondence Address: LERNER AND GREENBERG, P.A., Post Office Box 2480, Hollywood, FL, 33022-2480, US

(21) Appl. No.: 10/208,678

(22) Filed: Jul. 30, 2002

(30) Foreign Application Priority Data
Jul. 30, 2001 (DE) 101 37 099.7

(51) Int. Cl. G03F 7/039; G03F 7/40

(52) U.S. Cl. 430/280.1; 430/270.1; 430/323; 430/326; 430/313

(57) ABSTRACT

A chemically amplified photoresist contains acid-labile groups at least some of which have been fluorinated. As a result, the transparency of the photoresist at low wavelengths is increased. Further, the elimination of the fluorinated acid-labile protective groups lowers the degree of fluorination of the polymer, so raising the solubility of the polymer in polar solvents. A process for structuring substrates is also included.

### BACKGROUND OF THE INVENTION

1. FIELD OF THE INVENTION

The invention relates to a chemically amplified photoresist and process for structuring substrates having resist copolymers with enhanced transparency resulting from fluorinating the photochemically cleavable leaving groups and being applicable to 157 nm photolithography.

In order to raise the calculating speed of the processors and the capacity of memory elements, and to lower the costs of the components, the semiconductor industry is developing chips that have ever smaller features and hence an ever-increasing density of components. One particular challenge in this context is to reduce the minimum feature size. In optical lithography, these challenges have to date been mastered by the transition to smaller and smaller wavelengths. At a feature size of 100 to 70 nm, however, the existing processes, which use wavelengths down to 193 nm, approach the limit of their resolution. Therefore, the development of new processes is necessary. Particularly good prospects for industrial usefulness are possessed by optical lithography, which carries out exposure using radiation with a wavelength of 157 nm, because in this case chip manufacturers are able to continue utilizing their extensive knowledge of optical lithography. One major difficulty in employing exposure radiation with a wavelength of 157 nm is the unsatisfactory transparency of the materials that have been used to date. For industrial application, the base polymer in this high-resolution resist must possess an extremely high transparency, while the photochemicals with which, for example, an acid is generated in the resist are required to exhibit a high quantum yield.

In order to be able to achieve comprehensive chemical modification of the photoresist even at low exposure intensities, the majority of the resists in use at present operate with what is known as chemical amplification. In such systems, exposure initiates a photoreaction that catalyzes a change in the chemical structure of the photoresist. In the case of a positive-working, chemically-amplified resist, for example, exposure generates a strong acid, which in a subsequent heat treatment step brings about catalytic transformation or cleavage of the resist. This chemical reaction drastically alters the solubility of the polymer in a developer, so that a marked differentiation between exposed and unexposed areas is possible.

The structured (or patterned) photoresists can be used as masks for further operations, such as dry etch operations, for instance. Where the photoresist is used to pattern an underlying organic-chemical medium, such as in two-layer resists, the topmost layer, including the photoresist, must exhibit a high etch resistance. For this purpose, the photoresist either may have corresponding groups in the polymer chain or pendantly, such as silicon-containing groups, or the photoresist is amplified in a step that follows the patterning of the photoresist. For this, there must be reactive groups in the polymer, as anchor groups. These groups then react with a suitable reactive group in an amplifying reagent, which acts as a linking group, with formation of a chemical bond. In this way, silicon-containing groups or aromatic groups can be introduced subsequently into the polymer. The etch resistance of aromatic and organosilicon compounds in an oxygen plasma is much higher than that of aliphatic hydrocarbon compounds. Particularly for resist structures with a low layer thickness, the subsequent amplification of those structures is advantageous. The reaction incorporating organosilicon compounds is often termed silylation, the incorporation of aromatic compounds is called aromatization.

A process for consolidating structured resists is described, for example, in commonly-owned European Patent No. EP 0 395 917 B1, which corresponds to U.S. Pat. Nos. 5,234,794 and 5,234,793. In that process, following their patterning, the photoresists which are used for an exposure wavelength of 248 and 193 nm are chemically reinforced in their etch resistance through the incorporation of organosilicon groups and so form a sufficiently stable etch mask. Where the layer thickness of the resist is sufficient, lateral growth can be used to achieve a widening of the structure and hence an increase in the resolution.

As already mentioned, the low transparency of the known photoresists at a wavelength of 157 nm impedes development of the 157 nm technology. With prior-art photoresists, the maximum realizable layer thicknesses are 50 nm. Presently, photoresists are being developed in which the transparency at short wavelengths has been increased through the introduction of fluorine atoms. See Patterson et al., Proc. SPIE, 3999 (2000). Nevertheless, the absorption of these polymers is about 50 times higher than that of the present-day polymers in the resists used industrially for exposure with radiation having a wavelength of 193 or 248 nm. Even with these highly fluorinated polymers, thicknesses of only up to 200 nm are obtained at 157 nm. Moreover, there are also difficulties in developing the exposed photoresist, since the introduction of fluorine atoms into the polymer intensifies its hydrophobic properties. Accordingly, the detachment of the exposed areas from the substrate using an aqueous developer becomes more difficult. Furthermore, a high degree of fluorination of the polymer impairs the adhesion of the photoresist to the substrate.

### SUMMARY OF THE INVENTION

It is accordingly an object of the invention to provide a chemically amplified photoresist and process for structuring substrates having resist copolymers with enhanced transparency resulting from fluorinating the photochemically cleavable leaving groups and being applicable to 157 nm photolithography that overcome the hereinafore-mentioned disadvantages of the heretofore-known devices and processes of this general type and that provide a chemically amplified photoresist that exhibits increased transparency at short wavelengths, especially at a wavelength of 157 nm, and that permits simple development of the resist structure after exposure.

With the foregoing and other objects in view, there is provided, in accordance with the invention, a chemically amplified photoresist. The chemically amplified photoresist includes a polymer, a photoacid generator, and a solvent. The polymer includes acid-labile radicals attached to a polar group, so that following elimination of the acid-labile radicals the solubility of the polymer in polar developers is increased. At least a fraction of the acid-labile radicals are at least monofluorinated.

Through the use of at least partly fluorinated acid-labile radicals for the protection of the polar groups provided on the polymer, there is an increase in the transparency of the polymer at short wavelengths and hence also in the transparency of the photoresist. The fluorine groups give the polymer hydrophobic properties, so that it is relatively insoluble in aqueous alkaline developer solutions. Where the at least partly fluorinated, acid-labile radicals are eliminated from the polar groups under the influence of the acid liberated by exposure, the degree of fluorination of the polymer falls. As a result of which, it becomes more hydrophilic and dissolves more readily in polar developer solutions. Additionally, polar groups are liberated. Liberating the polar groups markedly increase the solubility of the polymer in polar developer solutions. This raises the contrast in dissolution properties between exposed and unexposed areas of the photoresist. For the photoresist polymer, it is possible to draw on known polymers such as are present in photoresists, but in which the acid-labile groups have been replaced at least in part by at least partly fluorinated acid-labile groups. In order to achieve an inventive enhancement in the transparency of the photoresist at short wavelengths, it is not necessary per se for the acid-labile groups to have been formed completely by at least partly fluorinated acid-labile groups. Some of the acid-labile groups may also be unfluorinated. The most marked increase in transparency is achieved, however, when all of the acid-labile groups are formed by at least partly fluorinated acid-labile groups.

Possible photoacid generators include all compounds that liberate an acid on exposure to radiation. Use is made advantageously of onium compounds, such as are described, for example, in European Patent Application No. EP 0 955 562 A1. Preferred photoacid generators are ionic compounds in the form of sulfonium salts and iodonium salts.

Possible resist solvents include methoxypropyl acetate, cyclopentanone, cyclohexanone, γ-butyro-lactone, ethyl lactate, diethylene glycol, diethyl ether, ethylene glycol dimethyl ether, dimethyl ether, or a mixture of at least two of these solvents. Generally, it is possible to use any customary solvents or mixtures thereof in which the components of the resist can be dissolved to form a clear, homogeneous, and storage-stable solution and which ensure good coat quality when the substrate is coated.

Besides the abovementioned components, the photoresist may include further constituents. For instance, the photoresist may include a thermoacid generator. Suitable thermoacid generators include benzylthiolanium compounds, for instance.

In addition, it is possible to add further components to the photoresist, as additives that influence the resist system advantageously in respect of resolution, film-forming properties, storage stability, radiation sensitivity, service life, etc. The chemically amplified resist includes the components mentioned above in general in the following proportions. These proportions relate to the weight of the photoresist:

film-forming polymer: 1-50% by weight, preferably 2-10% by weight;

photoacid generator: 0.001-10% by weight, preferably from 0.01 to 1% by weight; and

solvent: 50-99% by weight, preferably 88-97% by weight.

Where the photoresist includes a thermoacid generator, the thermoacid generator is present in a proportion between 0.01 and 5% by weight, preferably from 0.05 to 1% by weight.

The chemically amplified photoresist of the invention is configured as a positive resist, which is developed with a polar developer, in particular an aqueous-alkaline developer. In order to differentiate between exposed and unexposed areas, the polymer preferably includes polar groups protected by acid-labile groups. With particular preference, the polymer contains carboxyl groups or hydroxyl groups as polar groups. Carboxyl groups can be introduced, for example, by the (co)polymerization of suitable unsaturated carboxylic acids into the molecule. Examples of unsaturated carboxylic acids of this kind that have been esterified with acid-labile radicals are esters of acrylic acid, methacrylic acid, crotonic acid, or cinnamic acid. Examples of monomers with which hydroxyl groups can be introduced into the polymer are vinyl ethers, ω-hydroxy alkenes, which can also be branched, hydroxystyrenes, and hydroxycycloalkenes. Corresponding monomers are shown below.

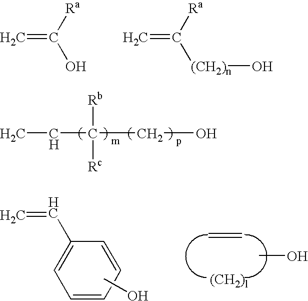

Wherein:

R^{a} has the following meanings: —F, —H, —CH₃, —CF₃, or a perfluorinated alkyl group having up to ten carbon atoms;

R^{b}, R^{c}, each independently, denote —H or an alkyl group having up to ten carbon atoms, which may also be branched;

n, m, p, and l each denote an integer between 1 and 10.

Particular preference is given to the monomers containing hydroxyl groups that have been protected with an acid-labile radical.

Possible acid-labile radicals include radicals that can be eliminated by acid. In accordance with the invention, these acid-labile radicals are at least monofluorinated and/or substituted by a fluoroalkyl group. A selective degree of fluorination of the radicals is particularly preferred, since this has beneficial effects on the transparency of the resist at low wavelengths. The acid-labile radicals are preferably selected from the group including tert-alkyl, isoalkyl radicals, other branched alkyl radicals having from 4 to 10 carbon atoms, tetrahydrofuranyl, tetrahydropyranyl, and tert-butoxycarbonyloxy radicals; these radicals are at least monofluorinated. Suitable acid-labile radicals are shown below.

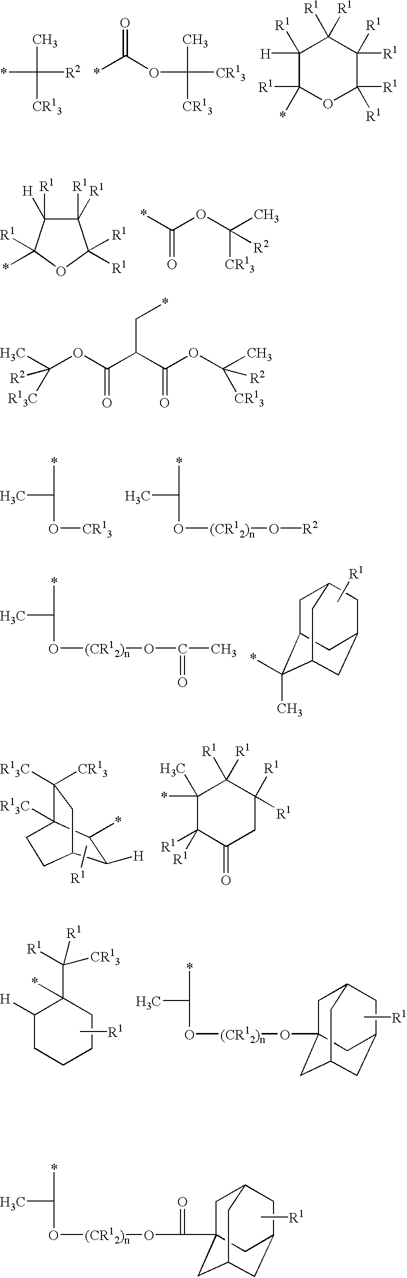

wherein:

R¹ denotes for each position independently a fluorine or a hydrogen atom;

CR¹₃ group may therefore be a —CF₃, a —CF₂H, a —CFH₂ or a —CH₃ group; and

R² denotes an alkyl group having from 1 to 10 carbon atoms, which may also have been partly or fully fluorinated.

Further, it is also possible to use acid-labile groups that are attached via an acetyl to a hydroxyl group of the polymer. Acid-labile groups of this kind can be introduced into the polymer, for example, by reacting the hydroxyl group of the polymer with at least monofluorinated aldehydes.

Other features which are considered as characteristic for the invention are set forth in the appended claims.

Although the invention is illustrated and described herein as embodied in a chemically amplified photoresist and process for structuring substrates having resist copolymers with enhanced transparency resulting from fluorinating the photochemically cleavable leaving groups and being applicable to 157 nm photolithography, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying examples.

### DESCRIPTION OF THE PREFERRED EMBODIMENTS

In one preferred embodiment of the photoresist of the invention, not only the acid-labile groups of the polymer are at least partly fluorinated. In order to enhance further the transparency, the polymer may also contain other fluorinated groups. For example, repeating units may be provided which carry a hexafluoroisopropylidene group. This group makes it possible to increase the transparency of the polymer at short wavelengths markedly. One suitable comonomer is, for example, 1,1,1,3,3,3-hexafluoroisopropyl acrylate. Further, the polymer may contain first repeating units that contain a carboxyl group and are at least monofluorinated. The carboxyl group either may have been esterified with an acid-labile group or is already present in the polymer in free form and so improves the adhesion of the polymer on the substrate. With particular preference, the first repeating unit is derived from 2-(trifluoromethyl)acrylic acid and/or 2-fluoroacrylic acid. See Patterson et al. id.

Besides the first repeating units, the polymer may also include further repeating units to influence the properties of the photoresist. For instance, it has already been mentioned that the introduction of polar groups improves the adhesion of the photoresist on the substrate. A further possibility includes providing groups in the polymer that allow the developed and patterned resist to be amplified subsequently. For this purpose, the polymer present in the photoresist of the invention preferably includes second repeating units that contain a reactive anchor group. A reactive anchor group is a group that is able, without needing to be activated or liberated first of all, is able to undergo a chemical reaction with a linking group of an amplifying agent, the amplifying reagent being attached to the polymer with formation of a chemical bond. This is the principle that forms the basis, for example, of the abovementioned process for consolidating structured resists of commonly-owned European Patent No. EP 0 395 917 B1, which corresponds to U.S. Pat. Nos. 5,234,794 and 5,234,793.

In order to attain processing times appropriate for industrial application, the reactive anchor groups must have a sufficient reactivity. With particular preference, the reactive anchor group is selected from the group including acid anhydride, epoxide, and ketene. Among these groups, the acid anhydride groups are particularly preferred. The polymer of the photoresist of the invention therefore includes, in one preferred embodiment, a second repeating unit that is introduced into the polymer by copolymerization of an unsaturated carboxylic anhydride. With particular preference, the unsaturated carboxylic anhydride is selected from the group including maleic anhydride, itaconic anhydride, methacrylic anhydride, norbornenedicarboxylic anhydride, and cyclohexenedicarboxylic anhydride. These unsaturated carboxylic anhydrides are already used for preparing photoresist polymers, so that extensive knowledge concerning their processing is in existence. The preparation of the photoresist and its deployment in industrial production processes are thereby facilitated.

The photoresist of the invention exhibits an increased transparency for short-wavelength light, and so can be used by lithography to produce structures that have a critical feature dimension of less than 100 nm. The invention accordingly further provides a process for structuring substrates in which the substrate is coated with the above-described photoresist to give a photoresist film, the photoresist film is sectionally exposed to light having a wavelength of less than 200 nm, the exposed photoresist film is developed, with the photoresist forming a structure, and the structure is transferred to the substrate.

For exposure, it is particularly preferred to use light having a wavelength of 157 nm or 13 nm.

With the objects of the invention in view, there is also provided a process of the invention that is generally implemented by first coating a substrate, generally a silicon wafer, which may also have been patterned in preceding operating steps and in which electronic components may also already have been integrated, with the photoresist. It is also possible to use multilayer resists, in which case the fluorinated polymer is present in the topmost layer. Multilayer resists allow better focusing of the beam used for exposure in the photoresist layer. In this case, first, a bottom resist (for example, one made of novolac) is applied and the photoresist of the invention is applied to the bottom resist. The resist is applied to the substrate by known techniques: for example, spin coating, spraying, or dipping.

The solvent present in the photoresist is removed by drying and the dried photoresist film is then exposed. Exposure takes place by customary techniques; for example, by exposure using a photomask, by interference techniques, or by direct irradiation with, for example, an electron beam. Exposure is carried out using short wave light, especially radiation with a wavelength of 157 nm or 13 nm. In the exposed areas, an acid is liberated from the photoacid generator and eliminates the acid-labile protective groups of the polymer. The acid is catalytically active; that is, with one liberated proton it is possible to eliminate a large number of acid-labile protective groups. As a result, the photoresist reacts very sensitively to the quantity of light irradiated. The elimination of the acid-labile groups from the polymer can be accelerated by a treatment at elevated temperature. For this purpose, the substrate with the exposed resist is heated, so that in the exposed areas substantial elimination of the at least partly fluorinated acid-labile groups takes place. As a result of the elimination of the acid-labile, fluorine-containing groups, the degree of fluorination of the polymer is lowered and polar groups (such as carboxyl groups or acidic hydroxyl groups) are liberated. The consequence is a marked differentiation in the solubility of the polymer in polar developers between the exposed and unexposed areas.

Following the temperature treatment, the exposed resist is treated with a polar developer, and in the exposed areas, the polymer is detached from the substrate. The developer solution used can be, for example, a 2.38% strength solution of tetramethylammonium hydroxide in water. The substrate is then bare at the exposed areas, while the unexposed areas are still protected by the solid resist film.

Where appropriate anchor groups have been provided in the polymer, the patterned resist can now be amplified, thereby making it possible to widen the resist structures and to increase the etch resistance.

The pattern produced with the resist can then be transferred to the substrate. For this purpose, the substrate is etched, for example, with a plasma.

The invention is illustrated in more detail with reference to an example.

### General Preparation Procedures

A) Preparation of (Part-)Fluorinated Tert-Butyl Methacrylates

1 mol of methacryloyl chloride is dissolved in 1.5 l of anhydrous diethyl ether and the solution is cooled to 0° C. under inert gas. Then 1.1 mol of the corresponding fluorinated lithium alkoxide are added dropwise to 1 l of diethyl ether at a rate that prevents the temperature from exceeding 5° C. Following the addition, the mixture is heated under reflux at boiling for 3 hours and then cooled to room temperature. The reaction mixture is poured into 2 l of water and the organic phase is separated off and extracted with twice 100 ml of water. The combined organic phases are dried over sodium sulfate and the solvent is distilled under reduced pressure. The methacrylate is purified by vacuum distillation or, in the case of solid esters, by recrystallization.

In accordance with the general preparation procedure the following (part-)fluorinated methacrylates are obtained:

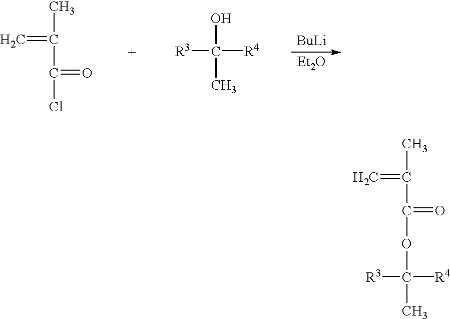

wherein:

R³═CF₃, R⁴═CH₃: 1,1,1-trifluoro-2-methylisopropyl ester (3F-tBuMA);

R³═R⁴═CF₃: 1,1,1,3,3,3-hexafluoro-2-methylisopropyl ester (6F-tBuMA);

b) Polymerization of the (Part-)Fluorinated Tert-Butyl Methacrylates and Copolymerization with Maleic Anhydride

The monomers obtained under a) were weighed out alone or in different weight fractions together with maleic anhydride and dissolved in butanone. The polymerization was initiated by adding azobisisobutyronitrile (1 mol %). After 24 hours, the copolymers obtained were precipitated from hexane. They were purified by multiple reprecipitation from hexane. Finally, the solid obtained was dried to constant weight under reduced pressure. For comparison, an unfluorinated polymethacrylate, a copolymer of unfluorinated methacrylate and maleic acid, and polymaleic anhydride were prepared analogously.

α) Homopolymerization

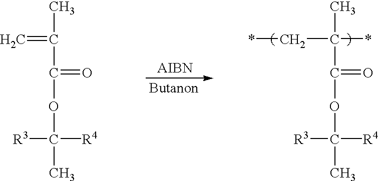

wherein:

R³═R⁴═CH₃: P(tBuMA)

R³═CF₃, R⁴═CH₃: P(3F-tBuMA)

R³═R⁴═CF₃: P(6F-tBuMA)

β) Copolymerization

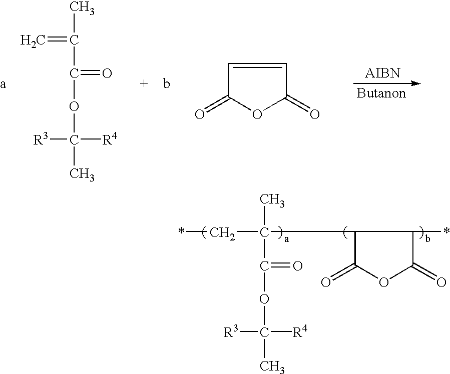

R³═CF₃, R⁴═CH₃; a=b=50 mol %: P(3F-tBuMA-co-MAAn)

R³═R⁴═CF₃; a=75 mol % b=25 mol %: P(GF-tBuMA-co-MAAn)

R³═R⁴═CH₃; a=b=50 mol %: P(tBuMA-co-MAAn)

b=100 mol %: P(MAAn)

c) Absorbance Measurements

The polymers/copolymers prepared under b) were subjected to measurement at a wavelength of 157 nm. The absorbances are reported below. For comparison, absorbances of nonfluorinated tert-butyl methacrylate and maleic anhydride are reported as well. The absorbance of the polymers can be reduced substantially by introducing fluorinated acid-labile groups.

TABLE 1
Absorbance of the Polymers at 157 Nm

| Polymer | a₁₅₇ (μm⁻¹) |
|---|---|
| P(tBuMa) | 4.8 |
| P(MAAn) | 10.8 |
| P(tBuMA-co-MAAn) | 6.2 |
| P(3F-tBuMA) | 3.35 |
| P(3F-tBuMA-co-MAAn) | 4.24 |
| P(6F-tBuMA) | 2.08 |
| P(6F-tBuMA-co-MAAn) | 2.89 |

We Claim:

1. A chemically amplified photoresist, comprising:
a polymer having a polar group and acid-labile radicals attached to said polar group, said polar group increasing solubility of said polymer in polar developers following elimination of said acid-labile radicals, at least a fraction of said acid-labile radicals being at least monofluorinated;
a photoacid generator; and
a solvent.

2. The photoresist according to claim 1, wherein said polar group of said polymer is selected from the group consisting of a carboxyl group and a hydroxyl group.

3. The photoresist according to claim 1, wherein:
said acid-labile radicals are selected from the group consisting of isoalkyl esters, tert-alkyl esters, branched alkyl esters having from 4 to 10 carbon atoms, tetrahydrofuranyl, etrahydropyranyl, and tert-butoxycarbonyloxy radicals; and
said acid-labile radicals are at least monofluorinated.

4. The photoresist according to claim 1, wherein said polar group of said polymer is a hydroxyl group and said at least partly-fluorinated, acid-labile radical is attached to said hydroxyl group with formation of one of an ether, ester, and acetal.

5. The photoresist according to claim 1, wherein said polymer includes repeating units, said repeating units containing a carboxyl group and being at least monofluorinated.

6. The photoresist according to claim 5, wherein said repeating units are derived from a material selected from the group consisting of 2-(trifluoro-methyl)acrylic acid and 2-fluoroacrylic acid.

7. The photoresist according to claim 5, wherein said polymer includes further repeating units containing reactive anchor groups.

8. The photoresist according to claim 7, wherein said reactive anchor groups are selected from the group consisting of acid anhydride, epoxide, and ketene.

9. The photoresist according to claim 7, wherein said further repeating units are derived from unsaturated carboxylic anhydrides.

10. The photoresist according to claim 9, wherein said unsaturated carboxylic anhydrides are selected from the group consisting of maleic anhydride, itaconic anhydride, methacrylic anhydride, norbornene-dicarboxylic anhydride, and cyclohexenedicarboxylic anhydride.

11. A process for structuring substrates, which comprises:
coating a substrate with a photoresist to yield a photoresist film, the photoresist including a polymer having a polar group and acid-labile radicals attached to the polar group, the polar groups increasing solubility of the polymer in polar developers following elimination of the acid-labile radicals, at least a fraction of the acid-labile radicals being at least monofluorinated, a photoacid generator, and a solvent;
sectionally exposing the photoresist film to light having a wavelength less than 200 nm;
developing the exposed photoresist film to form a structure; and
transferring the structure to the substrate.
